(19) United States
(12) Patent Application Publication
(10) Pub. No.: US 2008/0192454 A1
(43) Pub. Date: Aug. 14, 2008

(54) Arrangements for Telecommunication Equipment

(76) Inventor: Hans Knutsson, Lemvig (DK)

Correspondence Address: ERICSSON INC., 6300 LEGACY DRIVE, M/S EVR 1-C-11, PLANO, TX, 75024, US

(21) Appl. No.: 11/910,109

(22) PCT Filed: Apr. 1, 2005
(86) PCT No.: PCT/SE05/00477

§ 371 Date: Sep. 28, 2007

(51) Int. Cl. H05K 7/14

(52) U.S. Cl. 361/796

(57) ABSTRACT

The present invention relates to a subrack for housing printed boards in a telecommunication system wherein the subrack is adapted to be mounted in a rack, and the inner dimensions of the rack is such that it is adapted to mount printed boards of a first type via a plurality of conventional subracks. The subrack is adapted to mount at least one printed board of a second type essentially perpendicular, when mounted in the rack, compared to the printed boards of the first type mounted in the plurality of conventional subracks when mounted in the rack, wherein the size of at least one dimension of the or each printed board of the second type is greater than the size of at least one of the dimensions of the printed boards of the first type. Moreover, the invention relates to a cable adapter for connecting a connector of the rack comprising the subrack according to the invention to a printed board of the second type mounted in the subrack.

### FIELD OF THE INVENTION

The present invention relates to equipment for a telecommunication system, and more particularly to a subrack and to a cable adapter.

### BACKGROUND OF THE INVENTION

A rack, also denoted cabinet, is an enclosure for housing electronic equipment for a telecommunication system. Inside the rack a plurality of subracks are typically mounted, wherein each subrack is a metal frame or box equipped with electronic printed boards implementing the functionality for the telecommunication system. A backplane may also be included in the subrack for power-distribution. The rack is used for protecting the electronic equipment against e.g. electro magnetic compatibility (EMC), dust and unauthorized operation. The printed board comprises an isolating plate material with pre etched copper layers where the electronics components are fixed by soldering. The cabling required for the rack is line connections for the subscribers, power cabling for each subrack and uplink cabling from the subrack to the network.

Update of technology or expanded functionality in telecommunication systems implemented on printed boards installed in racks via subracks, often requires new racks and subracks, subscriber cabling and power cabling. The requirement of new racks, subscriber cabling and power cabling may depend on that the physical size of the printed board changes due to an update of the technology, such as an transition from circuit switched based technology to an Internet Protocol (IP) based technology, or to expanded functionality of the telecommunication system.

The present invention relates to the problem that physical dimensions of a new generation of telecommunication printed boards, based on Internet Protocol technology, and the associated subracks are not compatible with the dimensions of the existing racks, such as the racks of the applicant called BYB202.

The printed boards suitable for BYB202 are mounted in a subrack of BYB202. The size of the printed boards are 225×185 mm. The new generation of printed boards, has a size of 415×225 mm, and are mounted in the new Ericsson BYB501 subrack adapted for the new printed boards. The new printed board requires hence a new subrack, and also a new rack, called Ericsson BYB501. A replacement of the total system, i.e. racks and cabling, is hence required. A disadvantage with such a total replacement of racks and cabling is higher costs of updating the system. A further disadvantage is that a longer downtime for the connected subscribers is required, since the replacement of the total system requires a longer installing time than a replacement of only the printed boards and subracks.

Thus, the objective problem with the present invention is to provide arrangements that makes it possible to reuse the existing racks and cabling when at least one of the dimensions of the printed boards have changed.

### SUMMARY OF THE INVENTION

The objective problem is solved by the subrack according to claim 1 and by a cable adapter according to claim 7.

The subrack according to the present invention makes it possible to reuse the existing racks and cabling when at least one of the dimensions of the printed boards have changed which results in that the size of at least one dimension of the printed board of the second type is greater than the size of at least one of the dimensions of the printed boards of the first type. The subrack is adapted to mount at least one printed board of the second type essentially perpendicular, when mounted in the rack, compared to the printed boards of the first type mounted in the plurality of conventional subracks when mounted in the rack.

The cable adapter according to the present invention makes it possible to reuse the existing racks and cabling when at least one of the dimensions of the printed boards have changed which results in that the size of at least one dimension of the printed board of the second type is greater than the size of at least one of the dimensions of the printed boards of the first type. The cable adapter is arranged to connect a connector of the rack comprising the subrack according to the invention to the printed board of the second type mounted in the subrack. The cable adapter comprises at least one connector compatible with rack connectors of the rack, and at least one connector compatible with connectors of the printed board of the second type.

Preferred embodiments of the present invention are defined by the dependent claims.

An advantage with the present invention is that an easier update process of the system is provided.

A further advantage is that an update process requires a low labour.

A further advantage is that it provides a cost reduction for installation material such as rack and cabling for updating the system.

A yet further advantage with the present invention is that it gives a low downtime for the connected subscribers.

### BRIEF DESCRIPTION OF THE DRAWINGS

FIG. 1 shows an existing rack comprising a replacement subrack according to the present invention.

FIG. 2 shows a replacement subrack according to the present invention.

FIG. 3 shows a replacement subrack with cable adapter according to the present invention.

### BRIEF DESCRIPTION OF THE INVENTION

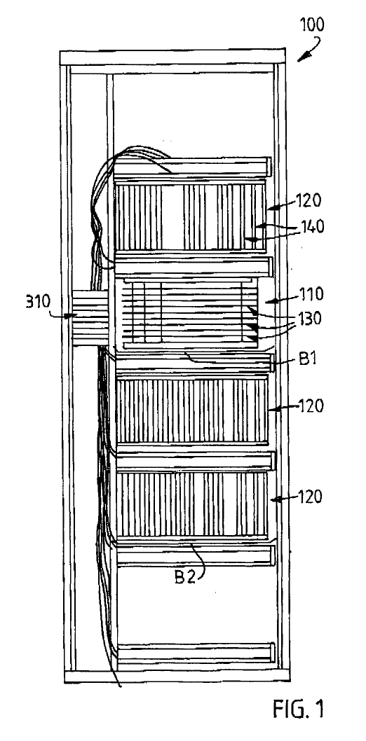

The present invention relates to equipment for a telecommunication system and is described in conjunction with FIGS. 1-3. The equipment comprises a rack 100 for housing electronic printed boards 210. The printed boards 210 are mounted in the rack 100 via a plurality of subracks 110, 210, 320 wherein the plurality of subracks 110, 210, 320 is adapted to be mounted in the rack 100.

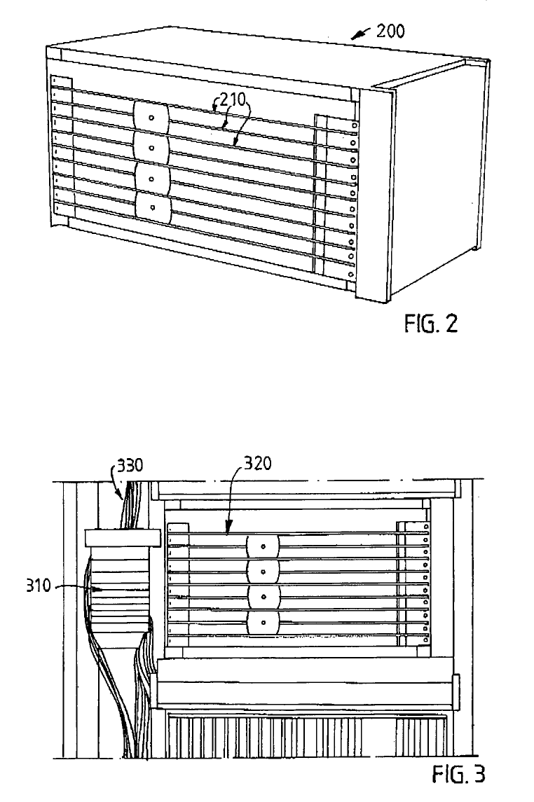

The present invention relates to a subrack 110, 200, 320 e.g. shown in FIG. 2 adapted to be mounted in a rack 100. The inner dimensions of the rack 100 is such that it is adapted to mount printed boards 140 of a first type having a first set of dimensions. The subrack 110, 200, 320 of the present invention is adapted to mount at least one printed board 130 of a second type, wherein at least one dimension of the or each printed board of the second type is greater than at least one of the dimensions of the first set of dimensions.

The subrack 110, 200, 320 of the invention has outer dimensions compatible with dimensions of available space inside the rack 100. The subrack 110, 200, 320 according to the present invention is also denoted replacement subrack, since it may replace a conventional subrack adapted to fit into the rack and to mount printed boards of the first type. The replacement subrack 110, 200, 320 is thus adapted to mount at least one printed board of the second type, wherein at least one dimension of the printed board of the second type is greater than at least one of the dimensions of the first set of dimensions which results in that the printed board 130,210 of the second type does not fit into the rack, by means of a conventional subrack 120 adapted for the printed board 140 of the first type. The subrack 110, 200, 320 of the invention makes it possible to mount printed boards 110 of the second type in the rack 100. That is achieved by the subrack 110, 200, 320 of the present invention that is adapted to mount at least one printed board 130, 210 of the second type essentially perpendicular, i.e. right angled, when mounted in the rack 100, compared to the printed boards 140 of the first type mounted in a conventional subrack 120 when mounted in the rack 100. In a preferred embodiment of the invention, the conventional subrack 120 mounts the printed boards 140 of the first type vertically while the subrack of the present invention mounts the or each printed board of the second type horizontally when the subrack of the embodiment and the conventional subrack are mounted in the rack.

Thus, a replacement subrack 110, 200, 320 according to the present invention designed with internal dimensions compatible with printed boards of the second type and with external dimensions compatible with available space inside the rack 100 is achieved thanks to that the replacement subrack 110, 200, 320 is adapted to mount the printing boards 130, 210 of the second type essentially perpendicular, when mounted in the rack 100, compared to the printed boards 140 of the first type mounted in a conventional subrack 120 when mounted in the rack 100.

The present invention also relates to a cable adapter 150, 310 for connecting a connector of the rack to the printed board of the second type. The cable adapter 150, 310 comprises a number of connectors compatible with rack connectors of the rack 100, cables, a number of connectors compatible with connectors in the printed boards 130, 210 of the second type. The cable adapter 150, 310 may be adapted for a subscriber connection, for a power connection, and for a combination thereof. Moreover, according to one preferred embodiment of the invention, the number of connectors are compatible with the connectors of the rack, preferably Ericsson BYB202 rack.

In preferred embodiments of the present invention, the printed board 130, 210 of the second type implements IP based functionality.

In a further embodiment of the present invention, the rack 100 is adapted to mount printed boards of the first type having a size of about 225×185 mm (height×depth). The rack 100 is preferably an Ericsson BYB202. The size of the printed board 130, 210 of the second type is preferably about 415×225 mm (height×depth).

According to one of the preferred embodiments, the subrack 110, 200, 320 is adapted to mount the printed boards 130, 210 of the second type horizontally, when mounted in the rack 100. Furthermore, the subrack 110, 200, 320 is adapted to mount one single printed board 130, 210 of the second type in each plane of the subrack according to FIGS. 1, 2 and 3. The width B 1 of the replacement subrack is essentially equal to the width B2 of the conventional subrack as shown in FIG. 1.

In the drawings and specification, there have been disclosed typical preferred embodiments of the invention and, although specific terms are employed, they are used in a generic and descriptive sense only and not for purposes of limitation, the scope of the invention being set forth in the following claims.

1. A subrack for housing printed circuit boards in a telecommunication system wherein the subrack is adapted to be mounted in a rack, and the inner dimensions of the rack is are configured to mount circuit printed boards of a first type via a plurality of conventional subracks is adapted is configured to mount at least one printed circuit board of a second type essentially perpendicular, when mounted in the rack, compared to the printed circuit boards of the first type mounted in the conventional subrack when mounted in the rack, wherein the size of at least one dimension of the or each printed circuit board of the second type is greater than the size of at least one of the dimensions of the printed circuit boards of the first type.

2. The subrack according to claim 1, wherein the subrack is configured to mount each printed circuit board of the second type essentially horizontally when mounted in the rack.

3. The subrack according to claim 1, wherein the printed circuit board of the second type implements IP based functionality.

4. The subrack according to claim 1, wherein the rack is configured to mount printed circuit boards having a size of 225×185 mm.

5. (Canceled)

6. The subrack according to claim 1, wherein the size of the printed circuit board of the second type is 415×225 mm.

7. A cable adapter for connecting a connector of a rack, the rack comprising a subrack for housing printed circuit boards in a telecommunication system the subrack being configured to be mounted in the rack, wherein the inner dimensions of the rack are configured to mount printed circuit boards of a first type via a plurality of conventional subracks, the first type of subrack being configured to mount at least one printed circuit board of a second type, essentially perpendicular to the printed circuit boards of the first type when mounted in the rack, wherein the size of at least one dimension of the printed circuit board of the second type is greater than the size of at least one of the dimensions of the printed circuit boards of the first type.

8. The cable adapter according to claim 7, wherein the adapter is configured for at least one subscriber connection.

9. The cable adapter according to claim 7, wherein the adapter is configured for at least one power connection.

10. The cable adapter according to claim 7, wherein the number of connectors are compatible with the number of connectors of the rack.

11. The cable adapter according to claim 7, wherein the printed circuit board of the second type implements IP based functionality.

12. The cable adapter according to claim 7, wherein the rack is configured to mount printed circuit boards having a size of about 225×185 mm.

13. (canceled)

14. The cable adapter according to claim 7, wherein the size of the printed circuit board of the second type is 415×225 mm.

15. The cable adapter according to claim 7, wherein the replacement subrack is configured to mount the printed circuit board of the second type essentially horizontally when mounted in the rack.
